(19) United States
(12) Patent Application Publication
(10) Pub. No.: US 2025/0266314 A1
(43) Pub. Date: Aug. 21, 2025

(54) MANUFACTURING METHOD OF ELECTRONIC PACKAGE

(71) Applicant: SILICONWARE PRECISION INDUSTRIES CO., LTD., Taichung City (TW)

(72) Inventors: Wen-Yu TENG, Taichung City (TW); Liang-Yi HUNG, Taichung City (TW); Chia-Cheng CHEN, Taichung City (TW); Yu-Po WANG, Taichung City (TW)

(73) Assignee: SILICONWARE PRECISION INDUSTRIES CO., LTD., Taichung City (TW)

(21) Appl. No.: 18/815,693

(22) Filed: Aug. 26, 2024

(30) Foreign Application Priority Data
Feb. 16, 2024 (TW) 113105527

(51) Int. Cl. H01L 23/367; H01L 23/00; H01L 23/373

(52) U.S. Cl. CPC H01L 23/367; H01L 23/3736; H01L 24/83; H01L 24/13; H01L 24/16; H01L 24/32; H01L 24/73; H01L 2224/10126; H01L 2224/13023; H01L 2224/16225; H01L 2224/32245; H01L 2224/73253; H01L 2224/83095; H01L 2224/8322; H01L 2924/351

(57) ABSTRACT

A manufacturing method of an electronic package is provided, which includes: disposing an electronic element and a heat dissipation structure on a carrier structure, wherein the heat dissipation structure is disposed on the electronic element by a heat conductor, and a flux material is sandwiched between the heat conductor and the heat dissipation structure and between the heat conductor and the electronic element; performing a first heating operation at a first temperature to vaporize the flux material; and performing a second heating operation at a second temperature to melt the heat conductor, and forming inter-metallic compound layers between the heat conductor and the heat dissipation structure and between the heat conductor and the electronic element.

### BACKGROUND

### 1. Technical Field

The present disclosure relates to a method of manufacturing an electronic package, and more particularly, to a method of manufacturing an electronic package with a heat dissipation structure.

### 2. Description of Related Art

With the rise and vigorous development of various applications and technologies that require high-speed computing, such as eSports games, high-resolution audio and video multimedia, and autonomous driving, as well as requirements for miniaturization of related equipment, the number of elements contained in a integrated circuit (IC) using a packaging structure such as a flip-chip ball grid array (FCBGA) has not only increased day by day, but also the processing and computing speed are getting faster and faster, such that the heat generated therefrom become more and more considerable, and the requirements for heat dissipation structures are also getting higher and higher.

FIG. 1 is a schematic cross-sectional view of a conventional semiconductor package 1. As shown in FIG. 1, the semiconductor package 1 comprises a packaging substrate 10, a semiconductor chip 11 mounted on an upper side of the packaging substrate 10 in a flip-chip manner and a heat sink 12, the heat sink 12 is disposed on a top surface of the semiconductor chip 11 through a thermal interface material (TIM) 13. In order to effectively bond the thermal interface material 13 with the heat sink 12 and the semiconductor chip 11, the heat sink 12 is generally connected to a partial position where the thermal interface material 13 is to be bonded, and a metal layer is then plated on the surface of the semiconductor chip 11 to which the thermal interface material 13 is to be bonded. In order to increase a coverage rate of the thermal interface material 13 on the semiconductor chip 11 and the heat sink 12, in addition to first melting the thermal interface material 13 through the reflow process, it is also required to apply a high temperature flux 14 with function of removing oxides between the semiconductor chip 11 and the thermal interface material 13 and between the heat sink 12 and the thermal interface material 13.

However, in the aforementioned reflow process, the temperature upon the thermal interface material 13 is melted (the melting temperature <156° C.) cannot completely volatilize the high temperature flux 14 (the volatilization temperature is >256° C.), resulting in that the high temperature flux 14 is still remaining up to 70% weight percentage, and the bubble 15 generated by the high temperature flux 14 will be wrapped in the melted thermal interface material 13 (liquid) and will not be dissipated easily, causing many voids in the thermal interface material 13 during cooling, and resulting in that the coverage rate of the thermal interface material 13 on the semiconductor chip 11 and the heat sink 12 is reduced, and further resulting in poor thermal conductivity, failure to achieve the heat dissipation target required by the product, and eventually the end product is damaged.

Therefore, there is a need for a solution that addresses the aforementioned shortcomings in the prior art.

### SUMMARY

In view of the aforementioned shortcomings of the prior art, the present disclosure provides a method of manufacturing an electronic package, which comprises: disposing an electronic element and a heat dissipation on a carrier structure, wherein the heat dissipation structure is disposed on the electronic element by a conductor, and a flux material is sandwiched between the conductor and the heat dissipation structure and between the conductor and the electronic element; performing a first heating operation at a first temperature to vaporize the flux material; and performing a second heating operation at a second temperature to melt the conductor, and forming inter-metallic compound layer between the heat conductor and the heat dissipation structure and between the heat conductor and the electronic element.

In the aforementioned method, the conductor is a thermal interface material layer.

In the aforementioned method, a material of the thermal interface material layer is metal indium or indium silver alloy.

In the aforementioned method, the second temperature is higher than the first temperature.

In the aforementioned method, the first temperature is higher than a boiling point of the flux material, but lower than a melting temperature of the conductor.

In the aforementioned method, the second temperature is higher than a melting temperature of the conductor.

In the aforementioned method, the flux material includes monocarboxylic acid.

In the aforementioned method, the monocarboxylic acid is formic acid, glycolic acid, glacial acetic acid, lactic acid, or a combination thereof.

In the aforementioned method, the monocarboxylic acid is diluted with a low boiling point solvent.

In the aforementioned method, the low boiling point solvent is isopropyl alcohol.

In the aforementioned method, an outer surface of the heat dissipation structure is disposed with a metal anti-oxidation layer.

In the aforementioned method, a material of the metal anti-oxidation layer is metal nickel.

In the aforementioned method, a material of the heat dissipation structure is metal copper.

As can be understood from the above, in the method of manufacturing method the electronic package of the present disclosure, the boiling point of the flux material is lower than the melting temperature of the heat conductor, and under the first heating operation at a lower temperature, the flux material is first vaporized without melting the heat conductor, and then melting the heat conductor under the second heating operation at a higher temperature, such that it can avoid the conventional problem of bubbles generated from high temperature flux penetrating into the molten thermal interface material. The method of manufacturing the electronic package of the present disclosure can be completed by using existing processes and equipment without a large amount of additional costs, also monocarboxylic acid is easy to be obtained, the required flux is easy to be prepared and has great variability.

### BRIEF DESCRIPTION OF THE DRAWINGS

FIG. 1 is a schematic cross-sectional view of a conventional semiconductor package.

FIG. 2A to FIG. 2C are schematic cross-sectional views of the manufacturing method of the electronic package of the present disclosure.

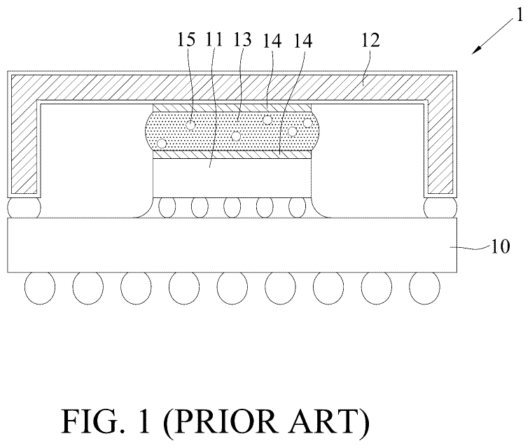

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “first,” “second,” “a,” and the like are for illustrative purposes, and are not meant to limit the scope implementable by the present disclosure. Any changes or adjustments made to the relative relationships, without substantially modifying the technical contents, are also to be construed as within the scope implementable by the present disclosure.

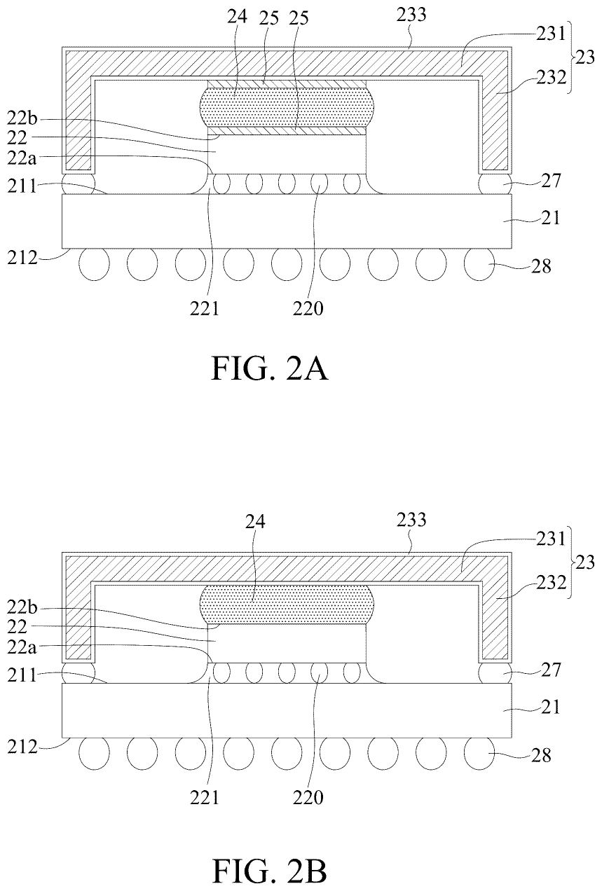

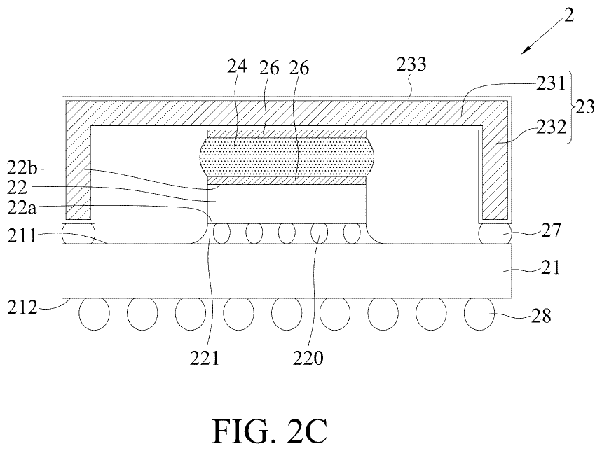

FIG. 2A to FIG. 2C are schematic cross-sectional views of the manufacturing method of the electronic package 2 of the present disclosure.

As shown in FIG. 2A, at least an electronic element 22 is provided on a carrier structure 21, and a heat dissipation structure 23 is connected to the electronic element 22 by a heat conductor 24, a flux material 25 is sandwiched between the heat conductor 24 and the heat dissipation structure 23, and the flux material 25 is also sandwiched between the heat conductor 24 and the electronic element 22.

The carrier structure 21 is, for example, a packaging substrate with a circuit layer, a through silicon interposer (TSI) with through-silicon vias (TSV), or other types of board, and the carrier structure 21 has a first surface 211 and a second surface 212 opposing the first surface 211, the circuit layer is, for example, a redistribution layer (RDL).

It can be understood that the carrier structure 21 can also be a base, an element, or a structure of other carrier elements, such as a lead frame or other board bodies with metal routing, etc., but the present disclosure is not limited to as such.

The electronic element 22 can be an active element, a passive element, a package module, or a combination thereof, and the active element may be a semiconductor chip, the passive element may be a resistor, a capacitor, and an inductor, etc.

In an embodiment, the electronic element 22 is a semiconductor chip, the electronic element 22 has an active surface 22a and an inactive surface 22b opposing the active surface 22a, and the active surface 22a is electrically connected to a circuit layer of the carrier structure 21 by a plurality of conductive bumps 220 in a flip-chip manner and is electrically connected to the circuit layer, and an underfill 221 is formed between the first surface 211 of the carrier structure 21 and the active surface 22a to encapsulate each conductive bump 220, or the electronic element 22 can be directly contacted to the circuit layer of the carrier structure 21. However, the way related to the electronic element 22 electrically connected to the carrier structure 21 is not limited to the above.

The heat dissipated structure 23 is, for example, a heat sink, a heat dissipation lid or other elements or structures with equivalent functions. In an embodiment, a heat dissipation lid is used for example, the heat structure 23 has a top sheet 231 and supporting legs 232 extended from the top sheet 231. The supporting legs 232 are fixed on the first surface 211 of the carrier structure 21 around the electronic element 22 by a bonding layer 27, so the top sheet 231 faces the inactive surface 22b of the electronic element 22.

The main material of the heat dissipation structure 23 is metal copper. In order to protect the heat dissipation structure 23 from being oxidized by the external environment, a metal anti-oxidation layer 233, such as metal nickel (Ni), can be formed on the outer surface of the heat dissipation structure 23.

The heat conductor 24 is disposed between the inactive surface 22b of the electronic element 22 and the top sheet 231 of the heat dissipation structure 23, such that the heats generated from the electronic element 22 are conducted more efficiently to the heat dissipation structure 23 and dissipated to environment thereafter. Preferably, the heat conductor 24 is a thermal interface material (TIM) layer, the main material of which is metal indium (In) or indium silver (In/Ag) alloy, wherein the indium silver alloy can be, for example, In₃Ag (In content 97%, boiling point is 143° C.) or In₁₀Ag (In content 90%, boiling point is 143° C. to 237° C.), but the present disclosure is not limited to as such, as long as it is a thermal interface material with low temperature metal.

In addition, an interface metal layer can be plated on the inactive surface 22b of the electronic element 22, such as a stacked multi-layer metal layer with metal materials like nickel, gold, chromium, palladium, etc., to use with the flux material 25 to enhance the bonding strength between the heat conductor 24 and the electronic element 22.

In an embodiment, the flux material 25 includes monocarboxylic acid (R—COOH), wherein the monocarboxylic acid is formic acid (boiling point is 101° C.), glycolic acid (boiling point is 100° C.), glacial acetic acid (boiling point is 118° C.), lactic acid (boiling point is 122° C.), or a combination thereof, that is, the boiling point of the flux material 25 can be between 100° C. and 122° C., but the present disclosure is not limited to as such. In addition, monocarboxylic acid is diluted with a solvent with low boiling point, and the low boiling point solvent is, for example, isopropyl alcohol (IPA), but the present disclosure is not limited as such.

In addition, a plurality of conductive elements 28 such as solder balls can be arranged on the second surface 212 of the carrier structure 21, so that the electronic package 2 can be disposed on an electronic device (not shown) such as a circuit board by the conductive elements 28.

As shown in FIG. 2B, the first heating operation is performed at the first temperature, such that the flux material 25 begins to remove oxides and vaporize. In this embodiment, the first temperature is higher than the boiling point of the flux material 25, but lower than the melting temperature of the heat conductor 24. For example, when the heat conductor 24 is metal indium and the flux material 25 is formic acid, the first temperature only needs to be higher than 101° C. and lower than 156° C., so that the flux material 25 is vaporized, but the heat conductor 24 is still not melted. For another example, when the heat conductor 24 is In₁₀Ag and the flux material 25 is lactic acid, the first temperature only needs to be higher than 122° C. and lower than 143° C., and the rest are analogous and will not be described again.

As shown in FIG. 2C, after completing the first heating operation, the second heating operation is performed at the second temperature, such that the heat conductor 24 is melted and an inter-metallic compound (IMC) layer 26 is formed between the heat conductor 24 and the heat dissipation structure 23, and the inter-metallic compound layer 26 is also formed between the heat conductor 24 and the metal layer of the inactive surface 22b of the electronic element 22, so that the connections between the heat dissipation structure 23, the heat conductor 24 and the electronic element 22 are formed firmly to improve the heat dissipation effect, thereby obtaining the electronic package 2 of the present disclosure. In an embodiment, the second temperature is higher than the first temperature, and the second temperature is higher than the melting temperature of the heat conductor 24, for example, when the heat conductor 24 is metal indium, the second temperature only needs to be higher than 156° C., and the rest are analogous and will not be described again.

In view of the above, in the manufacturing method of the electronic package of the present disclosure, the boiling point of the flux material is lower than the melting temperature of the heat conductor, and under the first heating operation at a lower temperature, the flux material is first vaporized without melting the heat conductor, and then melting the heat conductor under the second heating operation at a higher temperature, such that it can avoid the conventional problem of bubbles generated from high temperature flux penetrating into the molten thermal interface material. The method of manufacturing the electronic package of the present disclosure can be completed by using existing processes and equipment without a large amount of additional costs, also monocarboxylic acid is easy to be obtained, the required flux is easy to be prepared and has great variability.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A method of manufacturing an electronic package, comprising:
disposing an electronic element and a heat dissipation on a carrier structure, wherein the heat dissipation structure is disposed on the electronic element by a conductor, and a flux material is sandwiched between the conductor and the heat dissipation structure and between the conductor and the electronic element;
performing a first heating operation at a first temperature to vaporize the flux material; and
performing a second heating operation at a second temperature to melt the conductor, and forming inter-metallic compound layers between the heat conductor and the heat dissipation structure and between the heat conductor and the electronic element.

2. The method of claim 1, wherein the conductor is a thermal interface material layer.

3. The method of claim 2, wherein a material of the thermal interface material layer is metal indium or indium silver alloy.

4. The method of claim 1, wherein the second temperature is higher than the first temperature.

5. The method of claim 4, wherein the first temperature is higher than a boiling point of the flux material, and lower than a melting temperature of the conductor.

6. The method of claim 4, wherein the second temperature is higher than a melting temperature of the conductor.

7. The method of claim 1, wherein the flux material including monocarboxylic acid.

8. The method of claim 7, wherein the monocarboxylic acid is formic acid, glycolic acid, glacial acetic acid, lactic acid, or a combination thereof.

9. The method of claim 7, wherein the monocarboxylic acid is diluted with a low boiling point solvent.

10. The method of claim 9, wherein the low boiling point solvent is isopropyl alcohol.

11. The method of claim 1, wherein an outer surface of the heat dissipation structure is disposed with a metal anti-oxidation layer.

12. The method of claim 11, wherein the material of the metal anti-oxidation layer is metal nickel.

13. The method of claim 1, wherein a material of the heat dissipation structure is metal copper.

14. The method of claim 1, wherein an inactive surface of the electronic element can be plated with an interface metal layer, and the interface metal layer is a stacked multi-layer metal layer.
